(19) United States
(12) Patent Application Publication
(10) Pub. No.: US 2003/0160283 A1
(43) Pub. Date: Aug. 28, 2003

(54) Thin film transistor and display apparatus with the same

(75) Inventors: Jun Tanaka, Kawasaki (JP); Miharu Otani, Yokohama (JP); Kiyoshi Ogata, Tokyo (JP); Takuo Tamura, Yokohama (JP); Kazuhiko Horikoshi, Yokohama (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hitachi, Ltd., Tokyo (JP)

(21) Appl. No.: 10/201,423

(22) Filed: Jul. 22, 2002

(30) Foreign Application Priority Data
Feb. 26, 2002 (JP) 2002-048945
May 15, 2002 (JP) 2002-139411

(51) Int. Cl. H01L 27/01; H01L 27/12; H01L 23/62

(52) U.S. Cl. 257/347; 257/359

(57) ABSTRACT

An insulation film in a thin film transistor is an insulation film formed by heating a coating film having a hydrogen silsesquioxane compound or a methyl silsesquioxane compound as its principal component. By designing the insulation film so as to have pores mainly of a diameter of 4 nm or less, the dielectric constant of the insulation film can thereby be lowered. As a result, it is possible to improve the operating speed of the thin film transistor. Thus, improvement in the operating speed of a thin film transistor structure is thereby realized.

### CROSS-REFERENCES TO RELATED APPLICATIONS

Not applicable

### STATEMENT AS TO RIGHTS TO INVENTIONS MADE UNDER FEDERALLY SPONSORED RESEARCH OR DEVELOPMENT

Not applicable

### REFERENCE TO A “SEQUENCE LISTING,” TABLE, OR A COMPUTER PROGRAM LISTING APPENDIX SUBMITTED ON A COMPACT DISK

Not applicable

### BACKGROUND OF THE INVENTION

The present invention relates to a thin film transistor, and particularly to a thin film transistor (hereinafter referred to as TFT) for constituting a pixel switching device or driving circuit on an insulation substrate such as glass or silicon, and to a liquid crystal display and self-emitting display incorporating such thin film transistor.

TFTs are used as transistors for pixel-switching devices or driving circuits in active matrix liquid crystal displays. Moreover, TFTs have recently been used as transistors for pixel-switching devices or driving circuits in organic electro-luminescence devices (organic light-emitting diode (OLED) display), which have attracted attention as self-emitting displays.

In conventional TFTs, amorphous silicon (hereinafter referred to as a-Si) is often used as the transistor material, resulting in slow switching speed owing to low carrier mobility. Consequently, it was necessary to separately mount a pixel-driving LSI in the periphery of the substrate.

Currently, as described in Japanese Patent Laid-Open Publication No. H5-145074, the development of TFT devices employing polycrystalline silicon (hereinafter referred to as p-Si), which has high carrier mobility as transistor material is being actively conducted. The fast switching speed of p-Si allows transistor devices to be miniaturized, and the driving circuit can be integrally formed on the same substrate as the TFT device. Thus, reduction of manufacturing costs can be sought through the reduction of manufacturing steps and a reduction in the number of components, thereby realizing the manufacture of high-resolution TFT substrates at low cost.

With the p-Si TFT manufacturing method, a low-temperature excimer laser crystallization technology referred to as poly-Si TFT is becoming widely used. An excimer laser is employed for the crystallization, which enables the process temperature to be 450° C. or less, forming a p-Si TFT device on a glass substrate having lower heat resistance in comparison to quartz.

Furthermore, lasers are also being used to increase the carrier mobility in crystallization. For example, in the technology disclosed in “2001 International Workshop on Active Matrix Liquid Crystal Displays” (The Jpn. Society of Appl. Phys., pp. 71-74 (July 2001), with the low-temperature poly-Si TFT, in addition to integrally forming a pixel-driving transistor and driving circuit on the same substrate, a Digital Analogue Converter DAC (DAC) circuit was built in the substrate, and a memory circuit storing pixel information was built in the pixel area in order to develop further sophisticated and efficient displays.

### BRIEF SUMMARY OF THE INVENTION

There are several problems in conventional low-temperature poly-Si thin film transistors. To improve performance as an active matrix display, it is necessary to improve the operation speed of the TFT circuit itself, including the built-in driving circuit, in addition to increasing the switching speed by improving the p-Si crystallization.

A method of improving the operation speed of the TFT circuit is to optimize the TFT device structure and improve the crystallinity thereof, or to reduce the wiring resistance of the TFT circuit, or to reduce the parasitic capacitance among the wiring. In either case, it is necessary to improve performance while improving the manufacturing methods of materials, such as the wiring and insulation film in the TFT circuit.

The present invention solves the various problems described above, to provide a thin film transistor constituting a high-efficiency pixel-driving device and driving circuit on an insulation substrate such as glass or silicon, and a high-efficiency liquid crystal display and self-emitting display that incorporates the device.

To achieve the foregoing, this invention addresses the possibility of increasing the thin film transistor driving speed by lowering the dielectric constant of its insulation film material, thereby reducing the capacitance of the wiring.

In the present invention, the films forming the thin film transistor are underlying insulation film formed on the lower layer of the poly-Si film, a gate insulation film, a wiring interlayer insulation film, and a surface protection film (passivation film). One example, a p-MOS TFT is shown in FIG. 1, with the corresponding insulation film layers: including underlying insulation film 2, gate insulation film 6, interlayer insulation film 8 and surface protection film 11.

Conventionally, a silicon oxide film or silicon nitride film formed by CVD technology has been used to make these insulation films. The lowest dielectric constant of these materials thus has a value of about 4 for the silicon oxide film. It is possible to lower the dielectric constant of the insulation film by changing the deposition conditions of the CVD method. Nevertheless, the employment of plasma now widely used to form thin films by the CVD method may damage the semiconductor layer or electrode surface layer during deposition and affect the performance of the transistor.

One means for lowering the dielectric constant of the insulation film is use of an organic polymer insulation such as polyamide. Although an organic polymer is favorable in having a dielectric constant less than 4, it has the disadvantage of having less mechanical strength than an inorganic film. It also suffers from a high hygroscopic property and moisture permeability. Further, when this material is used as an interlayer insulation film, problems of device reliability arise, such as reduction in the mechanical strength of the device structure and erosion of the wiring by hygroscopic moisture.

Thus, while seeking to prevent damage to the semiconductor and wiring layers, a method of lowering the dielectric constant of the insulation film is desirable. In the present invention, this goal is achieved by forming an insulation film, which forms the thin film transistor comprising a semiconductor formed on the substrate, having a dielectric constant of 3.4 or less, minute pores, and SiO as its principal component. The films referred to are the underlying insulation film, gate insulation film, interlayer insulation film, surface protection insulation film, and the like, formed on a glass substrate. Moreover, the diameter of the pores in these insulation films is no less than 0.05 nm and no more than 4 nm, and preferably is no less than 0.05 nm and no more than 1 nm. Further, this insulation film is primarily composed of SiO. It is formed by heating a coating film having a hydrogen silsesquioxane compound or a methyl silsesquioxane compound as principal components.

To achieve this, an application solution having a hydrogen silsesquioxane compound as its principal component is prepared by dissolving a compound represented by a standard formula (HSiO/3/2)n in a solvent such as methylisobutylketone. This solution is applied on the substrate, and, after conducting intermediate heating at a temperature of 100° C. to 250° C., the coated substrate is heated at a temperature of 350° C. to 450° C. under an inert gas atmosphere such as a nitrogen atmosphere. The Si—O—Si bond is thereby formed in a ladder structure, and an insulation film having SiO as its principal component is ultimately formed.

An application solution having a methyl silsesquioxane compound as its principal component is prepared by dissolving a compound represented by a standard formula (CH3SiO3/2) in a solvent such as methylisobutylketone. This solution is applied on the substrate, and, after conducting intermediate heating at a temperature of 100° C. to 250° C., the coated substrate is heated at a temperature of 350° C. to 450° C. in an inert gas atmosphere, for example, a nitrogen atmosphere. The Si—O—Si bond is thus formed in a ladder structure, and an insulation film having SiO as its principal component results.

In an insulation film primarily composed of SiO and formed by heating a coating film having a hydrogen silsesquioxane compound or a methyl silsesquioxane compound as its principal component, as a method of controlling the diameter of the pores existing in the insulation film, there is, for example, a method in which the hydrogen silsesquioxane compound solution contains, in addition to containing to a solvent such as methylisobutylketone, a component having a higher pyrolysis temperature than such solvent, wherein traces of the component decomposed in the film are formed as the pores.

With this method, it is possible to change the decomposition behavior with the deposition temperature by variously selecting components having a high pyrolysis temperature. Thus, the pore diameter range can be contained within a selective range by controlling the formation process of the pores.

When forming a thin film transistor, an opening is formed on the insulation film. Because the insulation film has SiO as a principal component, similar to conventional oxide films and the like, etching gas may be used to form the opening. Therefore, there is an advantage in that a conventional silicon oxide film etching device may be used.

To apply a solvent for forming insulation films, the spin-coating method, slit-coating method or printing method may be employed. Furthermore, because the insulation film preferred for our invention is formed by heating this coating film, there is a superior advantage in that coating property differences are rare in comparison to the insulation film of the CVD method, even on densely formed minute wirings. Thus surface differences can thereby be eliminated.

In a TFT manufacturing line, the use of large glass substrates, for instance, 730×930 mm or 1000×1200 mm substrates, has recently become a mainstream practice. When forming an insulation film by the CVD method using these large substrates, a large deposition device becomes necessary, and the equipment cost substantially impacts the device cost. In contrast, with the present invention, because the insulation film is formed by the application/heating method, equipment cost is significantly reduced, thus reducing the investment costs of the manufacturing line. This helps reduce the device cost.

Further, with the present invention, it is preferable that the maximum heating temperature be within a range of 350° C. to 400° C. in the heating/forming step of the insulation material. It is possible to interface with the ordinary process of forming a thin film transistor composed mainly of amorphous silicon at a low temperature of 450° C. or less on a glass substrate.

Here, by employing the method of reducing the density in forming minute pores in the insulation film and approaching the vacuum dielectric constant, the dielectric constant of the insulation film can be made lower than the dielectric constant of the silicon oxide film. Particularly, by controlling the measurement and density of these minute pores, it is possible to form an insulation film having an arbitrary dielectric constant.

Nevertheless, if the diameter of the minute pores becomes large, the mechanical strength of the structure of the insulation film itself could deteriorate, or the leak current flowing in the insulation film could increase substantially and thereby reduce the withstand voltage characteristic of an insulation film. Thus, meticulous care must be given to the size of pores to be contained in the insulation film.

Accordingly, in the present invention, deterioration of the mechanical strength and breakdown voltage of the insulation film are improved by controlling the range of pore diameters. The principal pore diameter range is preferably 5.0 nm or less. When the principal diameter of pores is in a range of 1.0 nm or less, the dielectric constant of the insulation film will fall significantly below 4, and, when the principal diameter of pores is in a range of 2.0 nm or less or when the density of pores increases, the dielectric constant of the insulation film will be reduced further, and the value thereof will fall significantly below 3.

In the present invention to reduce the wiring resistance, the thin film transistor is formed with a circuit wiring employing aluminum as its principal component, or with a metal material having a resistivity lower than the aluminum. Examples of wiring materials having aluminum as their principal material are Al, Al-1% Si, Al-4% Cu, etc. Since it is possible to suppress the generation of helox, which becomes a problem on forming the foregoing wiring, when the insulation film forming temperature is in the range of 350° C. to 400° C., it is possible to realize a thin film transistor having high-efficiency characteristics.

Moreover, copper wiring may reduce the wiring resistance more than aluminum wiring. A thin film transistor having higher efficiency characteristics can be formed as a result of combining copper wiring and the aforementioned insulation film.

### BRIEF DESCRIPTION OF THE DRAWINGS

These and other features, objects and advantages of the present invention will become more apparent from the following description when taken in conjunction with the accompanying drawings wherein:

FIG. 1 is a cross section of a p-MOS thin film transistor for explaining a first embodiment;

FIG. 2 is a cross section of an n-MOS thin film transistor for explaining a second embodiment;

FIG. 3 is a diagram for explaining the creation and distribution of the pores in the insulation film of FIGS. 1 and 2;

FIG. 4 is a diagram for explaining the spectral transmittance of the insulation film having the pores shown in FIG. 3;

FIG. 5 is a diagram for explaining the creation and distribution of the pores in the insulation film of a third embodiment;

FIG. 6 is a cross section of a liquid crystal display for explaining a fourth embodiment;

FIG. 7 is a plan view of a liquid crystal display formed integrally on the same glass substrate together with a vertical driver circuit and horizontal driver circuit formed of p-MOS and n-MOS transistors; and

FIG. 8 is a cross section of an organic electro-luminescence self-emitting display for explaining a fifth embodiment.

### DESCRIPTION OF THE PREFERRED EMBODIMENTS

Embodiments of the present invention are now explained with reference to the drawings.

(Embodiment 1)

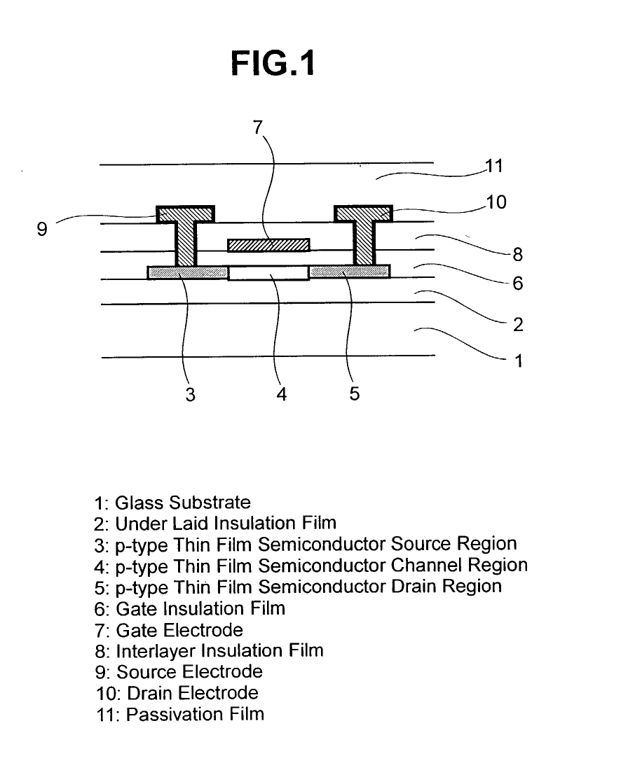

FIG. 1 is a cross-sectional view of a p-MOS thin film transistor in a first embodiment of the present invention. The method for manufacturing a p-MOS thin film transistor is discussed first.

After depositing an underlying insulation film 2 and an a-Si film on a non-alkali glass substrate 1, a pattern is formed after using well-known excimer laser crystallization technology to make the required area of the a-Si film into a polysilicon film. A p-type semiconductor thin film layer is then formed having a source region 3, a channel region 4 and a drain region 5. using impurity injection technology pursuant to well-known ion doping techniques. Thereafter, a gate insulation film 6, a gate electrode 7, and an interlayer insulation film 8 covering the above are successively laminated, and a source electrode 9 connected via the opening provided to the source region, a drain electrode 10 connected via the opening provided to the drain region, and a passivation film 11 for covering the foregoing device surfaces are formed to complete the p-MOS thin film transistor.

In the present invention, the formation of at least one of the layers among underlying insulation layer 2, gate insulation layer 6, interlayer insulation film 8 and passivation film 11 was performed as described in the following example using an interlayer insulation film. A methylisobutylketone solution having a hydrogen silsquioxane compound as its principal component was applied on the semiconductor thin film using a known application method, and the coated semiconductor was heated under a nitrogen atmosphere at 200° C. for 30 minutes. Furthermore, by additionally heating the coated semiconductor under a nitrogen atmosphere at 400° C. for 30 minutes, the Si—O—Si bond is formed in a ladder structure, and an insulation film having SiO as its principal component is thereby ultimately formed.

(Embodiment 2)

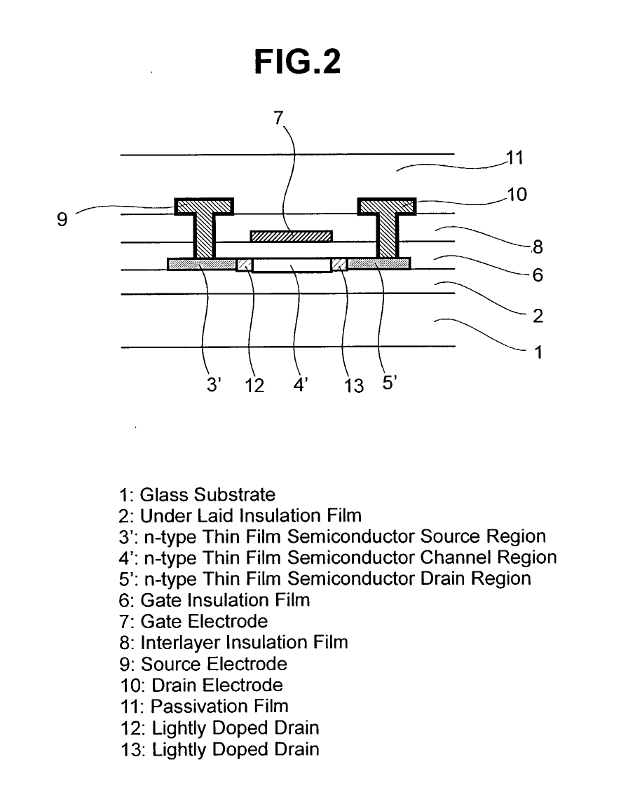

FIG. 2 is a cross-sectional view representing an n-MOS thin film transistor in a second embodiment of the present invention. In FIG. 2, the n-MOS thin film transistor is formed as described next. After depositing an underlying insulation film 2 and an a-Si film on a non-alkali gas substrate 1, at least a part of the a-Si film area is made into a polysilicon film with excimer laser crystallization technology. A pattern is formed on the polysilicon film, and an n-type semiconductor thin film layer comprising a source region 3, a channel region 4, a drain region 5, and a lightly doped drain region (LDD region) 12, 13 is formed by impurity injection technology such as ion doping. Then a gate insulation film 6, a gate electrode 7, and an interlayer insulation film 8 covering the above are formed on the upper side of the n-type semiconductor thin film layer. Next a source electrode 9 connected via the opening provided to the source region, a drain electrode 10 connected via the opening provided to the drain region, and a passivation film 11 for covering the foregoing device surfaces are formed to complete the n-MOS thin film transistor.

In this embodiment, a methylisobutylketone solution having a hydrogen silsesquioxane compound as its principal component is applied to at least one of the layers among the underlying insulation layer 2, gate insulation layer 6, interlayer insulation film 8 and passivation film 11. The coated product is then heated under a nitrogen atmosphere at 200° C. for 30 minutes, and further heated under a nitrogen atmosphere at 400° C. for 30 minutes to form an insulation film having SiO as its principal component, wherein the Si—O—Si bond is formed in a ladder structure. In FIG. 2, this insulation film is used for interlayer insulation film 8.

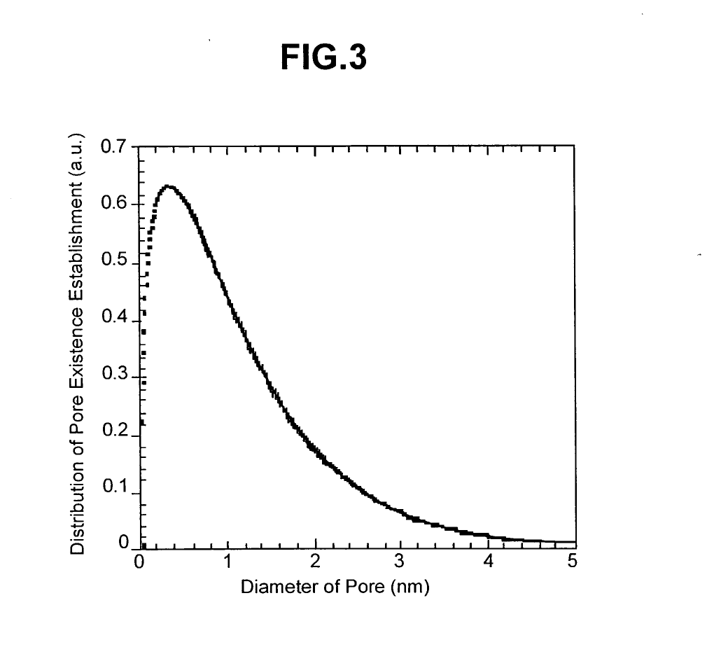

The insulation film employed in Embodiments 1 and 2 described above typically has a dielectric constant of 3.4 or less, preferably 3.0, and has pores in the insulation film. The principal diameter of such pores is in a range of 5.0 nm or less, particularly in a range of 1.0 nm or less. The creation and distribution of pores is shown in FIG. 3. Measurement of the distributed pores was conducted with an X-ray thin film structure analyzing device, ATX-G, manufactured by Rigaku Corporation. The measurement results are described below.

First, a methylisobutylketone solution having a hydrogen silsesquioxane compound as its principal component was applied to a substrate. This was heated under a nitrogen atmosphere at 200° C. for 30 minutes, and further heated under a nitrogen atmosphere at 400° C. for 30 minutes to form an insulation film having SiO as its principal component, wherein the Si—O—Si bond was formed in a ladder structure. With respect to the foregoing insulation film, the film thickness and film density thereof were measured by the X-ray reflectivity measurement method and the diffuse scattering X-ray component was measured thereafter. Based on the diffuse scattering measurement data, the scatterers, that is, the distribution of created pores were calculated by comparing the theoretical scattering strength pursuant to the scattering function in anticipation of the spherical scatterers.

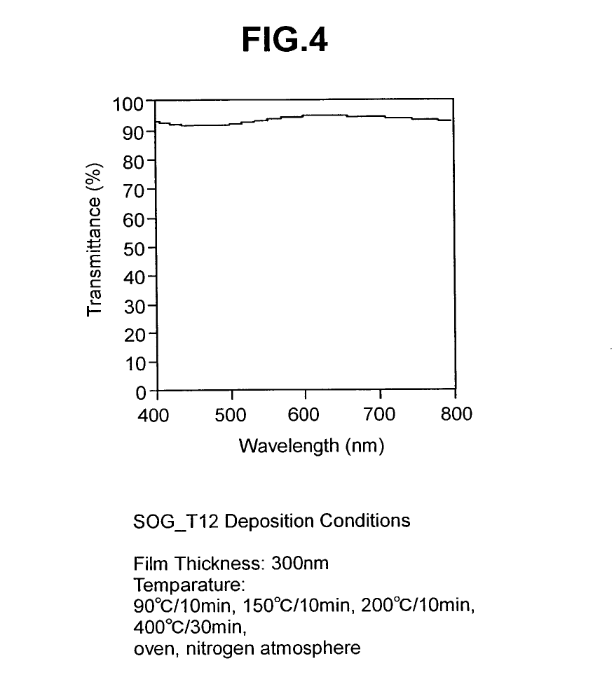

Moreover, with respect to this insulation film, a 50 mm angulate glass substrate having a thickness of 0.7 mm was formed, and, without a reference glass substrate, a U-4000 spectrophotometer manufactured by Hitachi, Ltd. was used to measure the spectral transmittance in the wavelength range of 400 nm to 800 nm, which is within the visible light area. The results are shown in FIG. 4. Transmittance showed 90% or more in the wavelength range of 400 nm to 800 nm. The transmittance did not attenuate at the short wavelengths, showed a steady high value, and had sufficient transmittance as a film material to be employed in displays.

When the insulation material internally comprising the pores shown in FIG. 3 is used as interlayer insulation film 8 of the embodiments of FIG. 1 or FIG. 2, the wiring delay time of the thin film transistor is shortened by approximately 20%, in comparison to a silicon oxide film made by a conventional CVD method. The source electrode 9 and drain electrode 10 in these embodiments were made of aluminum wiring.

(Embodiment 3)

In Embodiment 3 insulation film obtained by heating coating film having a hydrogen silsesquioxane compound as its principal component is applied to underlying insulation film 2, interlayer insulation film 8 and passivation film 11 of FIG. 1 or FIG. 2. The method of forming the insulation film is the same as in Embodiments 1 and 2 above, but the dielectric constant of the insulation film is roughly 2.5, and the principal diameter of the pores contained therein is in a range of 5.0 nm or less, and particularly in a range of 2.0 nm or less.

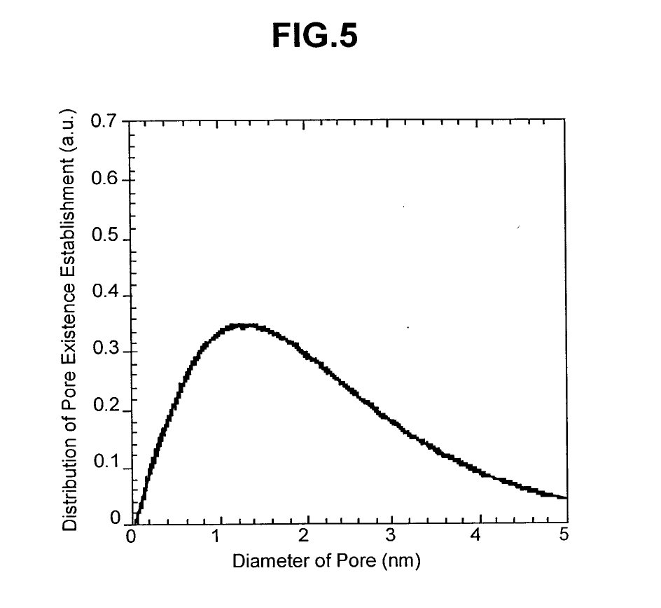

As was done for Embodiments 1 and 2 in FIG. 3, measurement results of the distribution of the created pores, conducted with the X-ray thin film structure analyzing device, ATX-G, manufactured by Rigaku Corporation are shown in FIG. 5. Similar to the results for Embodiment 2, the results for Embodiment 3 show that the wiring delay time is shortened by approximately 25% by employing the aforementioned insulation film to at least one layer among underlying insulation film 2, interlayer insulation film 8 and passivation film 11.

(Embodiment 4)

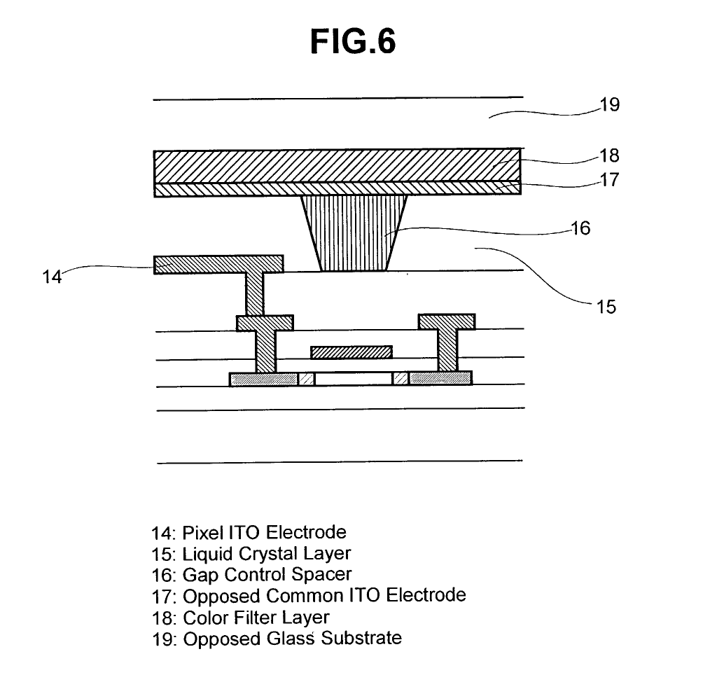

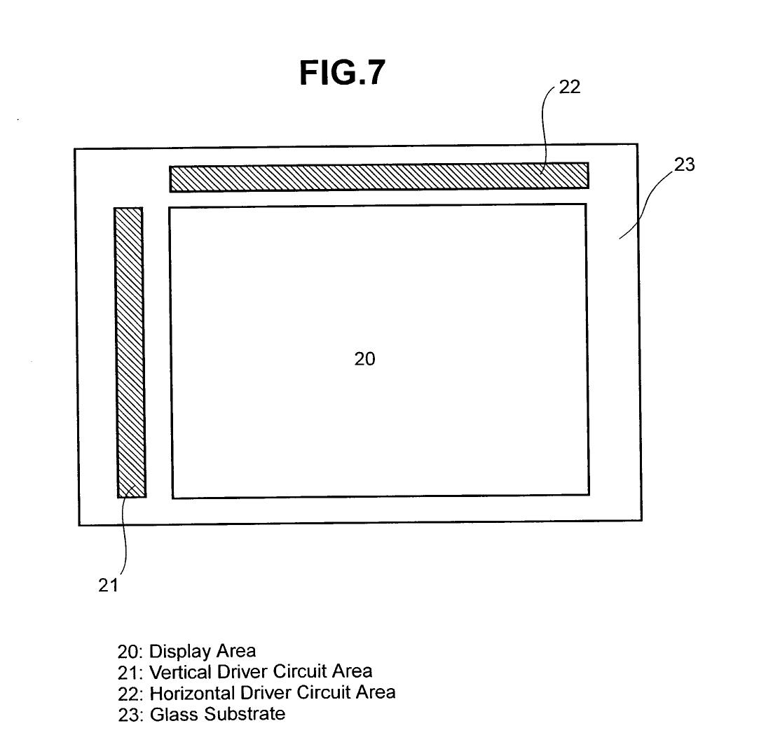

FIG. 6 is a schematic cross section of a liquid crystal display employing the thin film transistor explained in Embodiments 1 to 3. In the present embodiment, the driving circuit composed of the p-MOS and n-MOS thin film transistors formed in Embodiments 1 and 2 is disposed in the vicinity of the substrate as shown in FIG. 7, and the vertical driver circuit 21 and horizontal driver circuit 22 are formed integrally on the same glass substrate 23 as display area 20.

FIG. 6 shows a case where an ITO electrode 14 constituting the pixels is formed on passivation film 11 of the n-MOS thin film transistor shown in FIG. 2 as the pixel-driving transistor by connecting it to drain electrode 10 via the opening provided to passivation film 11. The structure of the liquid crystal display includes a color filter layer 18 on a glass substrate 19 facing glass substrate 1 (corresponding to the glass substrate 1 of FIG. 2) having the thin film transistor formed thereon, an opposed common ITO electrode layer 17 formed on color filter layer 18, a spacer 16 for controlling the gap with the TFT glass substrate 1, and a liquid crystal layer 15 in which the thickness thereof is determined by the spacer. In FIG. 6, the periphery of the substrate for introducing the liquid crystal is not shown. Moreover, although an example is presented where a top-gate, low-temperature, poly-Si, thin film transistor was used, the present invention shall in no way be limited to these embodiments.

(Embodiment 5)

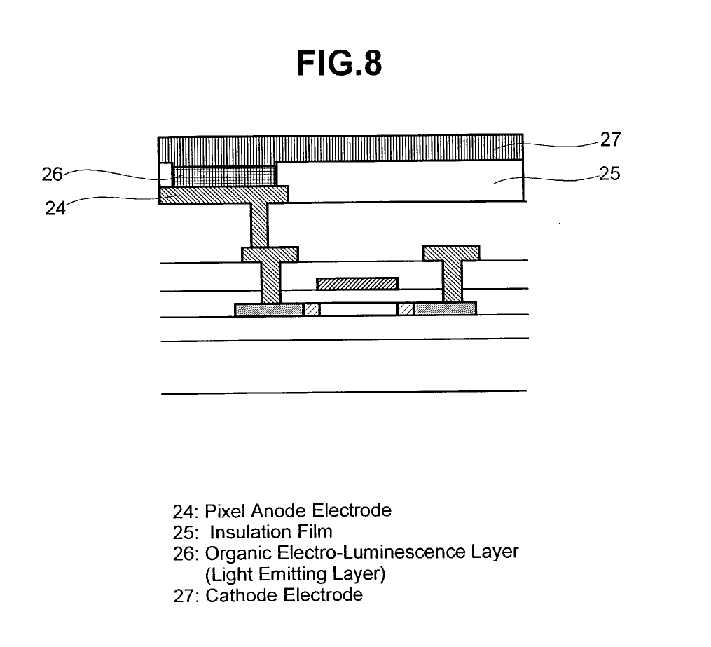

FIG. 8 is a schematic cross section of an organic electro-luminescence self-emitting display employing the thin film transistor described in Embodiments 1 to 3. In the present embodiment, the driving circuit composed of the p-MOS and n-MOS thin film transistors formed in Embodiment 1 or 2 is disposed in the vicinity of the substrate, and a vertical driver circuit 21 and horizontal driver circuit 22 are integrally formed on the same glass substrate as the display area.

In FIG. 8, the n-MOS thin film transistor shown in FIG. 2 is employed as the pixel-driving thin film transistor, a pixel anode electrode (ITO electrode) 24 is formed via the opening provided to the passivation film 11 thereof, and, thereafter, a separation insulation film 25 for separating the organic electro-luminescence layer 26 between the respective pixels is formed. In this embodiment, a polyamide material is used as the separation insulation film 25. Next, an organic electro-luminescence layer 26 is formed as the light-emitting layer, and a cathode electrode 27 is formed thereon, completing the organic electro-luminescence self-emitting display.

In the display described in Embodiments 4 and 5 above, the thin film transistor explained in Embodiments 1 to 3 drives the red, green and blue pixels. Because the insulation film constituting this thin film transistor internally includes pores having a prescribed diameter in at least one layer among an underlying insulation film, a gate insulation film, an interlayer insulation film or a surface insulation film, the stray capacitance of the thin film transistor can be reduced, and, as a result, the driving speed of the thin film transistor is improved.

As described above, by employing an insulation film having a low dielectric constant and minute pores in which the distribution of the created pores is controlled, it is possible to improve the performance of thin film transistors. Moreover, by employing the foregoing thin film transistor in a pixel-switching device or driving circuit, it is possible to improve the performance of liquid crystal displays and self-emitting displays.

While we have described several embodiments in accordance with our invention, it should be understood that the disclosed embodiments may be modified without departing from the scope of the invention. Therefore, the invention should not be construed as circumscribed by the details shown and described herein, but as intended to cover all such changes and modifications within the scope of the appended claims.

What is claimed is:

1. A thin film transistor comprising an insulation film and a semiconductor film on an upper side of a substrate, wherein the insulation film is an insulation film containing SiO, the thin film transistor includes minute pores in the insulation film, and the dielectric constant of the insulation film is about 3.4 or less.

2. A thin film transistor as in claim 1 wherein the thin film transistor contains pores in the insulation film mainly having a diameter of between 0.05 nm and 4 nm.

3. A thin film transistor as in claim 2 wherein the thin film transistor contains pores in the insulation film mainly having a diameter of between 0.05 nm and 1 nm.

4. A thin film transistor according to claim 1 wherein the insulation film is an insulation film formed by heating a coating film having a hydrogen silsesquioxane compound or a methyl silsesquioxane compound as its principal component.

5. A thin film transistor according to claim 2 wherein the insulation film is an insulation film formed by heating a coating film having a hydrogen silsesquioxane compound or a methyl silsesquioxane compound as its principal component.

6. A thin film transistor according to claim 1 wherein the transistor includes a polycrystalline silicon film formed by heat treatment of an amorphous silicon film.

7. A thin film transistor according to claim 2 wherein the transistor includes a polycrystalline silicon film formed by heat treatment of an amorphous silicon film.

8. A thin film transistor comprising an underlying insulation film, a gate insulation film, a semiconductor insulation film, an interlayer insulation film and a passivation film on the upper side of a substrate, wherein:
at least one of the insulation films is an insulation film containing SiO and contains pores mainly having a diameter of between 0.05 nm and 1 nm; and
the dielectric constant of the insulation film is 3.4 or less.

9. A thin film transistor according to claim 8 wherein the insulation film is an insulation film formed by heating a coating film having a hydrogen silsesquioxane compound or a methyl silsesquioxane compound as its principal component.

10. A liquid crystal display comprising a thin film transistor, wherein:
an insulation film forming a portion of the thin film transistor comprises an insulation film containing SiO;
the thin film transistor has minute pores in the insulation film; and
the dielectric constant of the insulation film is 3.4 or less.

11. A liquid crystal display according to claim 10 wherein the insulation film comprises at least one layer chosen from an underlying insulation film, a gate insulation film, a semiconductor insulation film, an interlayer insulation film and a passivation film formed on the upper side of a substrate.

12. A liquid crystal display according to claim 11 wherein the insulation film is an insulation film formed by heating a coating film having a hydrogen silsesquioxane compound or a methyl silsesquioxane compound as its principal component.

13. A liquid crystal display according to claim 12 wherein the liquid crystal display includes a semiconductor thin film comprising polycrystalline silicon formed by heat-treating an amorphous silicon film.

14. A liquid crystal display according to claim 10 wherein the thin film transistor comprises a circuit wiring formed by employing aluminum or a metal material having a resistivity smaller than the aluminum.

15. A self-emitting display comprising a thin film transistor, wherein:
an insulation film constituting the thin film transistor comprises an insulation film containing SiO,
the thin film transistor has minute pores in the insulation film, and
the dielectric constant of the insulation film is 3.4 or less.

16. A self-emitting display according to claim 15 wherein the insulation film is at least one layer among an underlying insulation film, a gate insulation film, a semiconductor insulation film an interlayer insulation film and a passivation film formed on the upper side of a substrate.

17. A self-emitting display according to claim 16 wherein the insulation film is an insulation film formed by heating a coating film having a hydrogen silsesquioxane compound or a methyl silsesquioxane compound as its principal component.

18. A self-emitting display according to claim 16 wherein the semiconductor thin film is a polycrystalline silicon film formed by heat-treating an amorphous silicon film.

19. A self-emitting display according to claim 16 wherein the thin film transistor comprises a circuit wiring formed by employing aluminum or a metal material having a resistivity smaller than the aluminum.
